(19) United States
(12) Patent Application Publication
(10) Pub. No.: US 2016/0226483 A1
(43) Pub. Date: Aug. 4, 2016

(54) CONTROL CIRCUIT AND ELECTRONIC DEVICE USING THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: CHUN-SHENG CHEN, New Taipei (TW); WEI ZHANG, WuHan (CN)

(21) Appl. No.: 14/737,711

(22) Filed: Jun. 12, 2015

(30) Foreign Application Priority Data
Feb. 2, 2015 (CN) 201510052613.4

(51) Int. Cl. H03K 17/687; H03K 17/60; G06F 1/26

(52) U.S. Cl. CPC H03K 17/687; G06F 1/26; H03K 17/602

(57) ABSTRACT

A control circuit includes a control module and a switch module. The control circuit is coupled between a power module and a connecting module. The control module includes a first port and a second port. The switch module including a first power terminal receives power from the power module. The first port is coupled to the power module. The control module detects power level in the power module through the first connector. The control module outputs different signals corresponding to the level of power in the power module. The switch module connects the connecting module to the power module or disconnects the connecting module from the power module depending on the signals received from the control module.

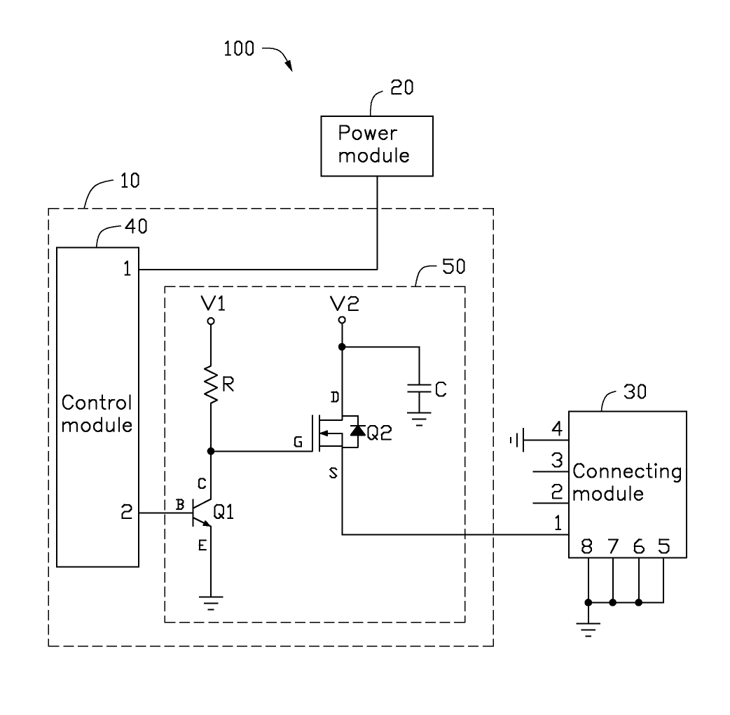

### FIELD

The subject matter herein generally relates to control circuitry.

### BACKGROUND

A universal serial bus (USB) device is usually charged by a battery of a notebook computer through a USB connector coupled to the notebook computer.

### BRIEF DESCRIPTION OF THE DRAWING

Implementations of the present technology will now be described, by way of example only, with reference to the attached FIGURE.

The FIGURE is a circuit diagram of an embodiment of an electronic device using a control circuit.

### DETAILED DESCRIPTION

Numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series and the like.

The FIGURE shows an electronic device 100 comprising a control circuit 10, a power module 20, and a connecting module 30. The control circuit 10 can comprise a control module 40 and a switch module 50.

In the embodiment, the electronic device 100 can be a notebook computer. The power module 20 can be a battery of the notebook computer. The power module 20 supplies power for the electronic device 100. The control module 40 can be an integrated controller in the notebook computer. The connecting module 30 can be a universal serial bus (USB) connector. The power module 20 supplies power for the connecting module 30 when the power module 20 is coupled to the connecting module. The connecting module 30 comprises a power pin 1, a signal pin 2, a signal pin 3, and ground pins 4-8. The signal pin 2 and the signal pin 3 are used to transmit signals when the electronic device 100 is coupled to an external USB device through the connecting module 30.

The control module 40 can comprise a first port 1 and a second port 2. The first port 1 is coupled to the power module 20 and the second port 2 is coupled to the switch module 50.

The switch module 50 can comprise power terminals V1 and V2, a resistor R, a capacitor C, and transistors Q1 and Q2. In the embodiment, the transistor q1 is a NPN transistor and the transistor Q2 is an n-channel FET. A base of the transistor Q1 as a control terminal is coupled to the second port 2 of the control module 40. An emitter of the transistor Q1 as a second terminal is grounded. A collector of the transistor Q1 as a first terminal is coupled to the power terminal V1 through the resistor R. A gate of the transistor Q2 as a control terminal is coupled to the collector of the transistor Q1. A drain of the transistor Q2 as a first terminal is coupled to the power terminal V2. A source of the transistor Q2 as a second terminal is coupled to the power pin of the connecting module 30. The drain of the transistor Q2 is also grounded through the capacitor C. In the embodiment, the power terminal V1 receives a first voltage from the power module 20 through a motherboard of the electronic device 100. The second power terminal V2 receives a second voltage from the power module 20 through the motherboard of the electronic device 100.

In use, the control module 40 detects a level of power in the power module 20 and outputs a control signal to the second port 2.

When the level of power in the power module 20 exceeds a preset value, the control signal is at a low level, such as logic 0. The transistor Q1 is turned off and the FET Q2 is turned on. The power terminal V2 is connected to the power pin 1 of the connecting module 30 and the second voltage is output to the connecting module 30.

When the level of power in the power module 20 does not exceed the preset value, the control signal is at a high level, such as logic 1. The transistor Q1 is turned on and the transistor Q2 is turned off. The power terminal V2 is disconnected from the power pin 1 of the connecting module 30 and the second voltage is not output to the connecting module 30, thus the power module stops supplying power for the connecting module.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A control circuit coupling a power module and a connecting module, the control circuit comprising:
a control module comprising a first port and a second port; and
a switch module comprising a first power terminal configured to receive power from the power module,
wherein the first port is coupled to the power module, the second port is coupled to the switch module, the switch module is coupled to the connecting module, the control module is configured to detect a level of power in the power module and output a control signal to the second port in event that the level of power in the power module exceeds a preset value, the power module supplies power for the connecting module; and
the switch module is configured to connect the first power terminal to the connecting module in event that the level of power in the power module does not exceed the preset value, the switch module disconnects the first power terminal from the connecting module, the power module stops supplying power for the connecting module.

2. The control circuit as claim 1, wherein the switch module further comprises a resistor, a first transistor, a second transistor, a control terminal of the first transistor is coupled to the second port of the control module, a first terminal of the first transistor is a second power terminal powered by the power module, a second terminal of the first transistor is grounded, a control terminal of the second transistor is couple to the first terminal of the first transistor, the first terminal of the second transistor is connected to the first power terminal, the second terminal of the second transistor is connected to the connecting module, the first transistor is turned on and the second transistor is turned off, the first transistor is turned off and the second transistor is turned on.

3. The control circuit as claim 2, wherein when the level of power in the power module exceeds the preset value, the first transistor is turned on and the second transistor is turned off, when the level of power in the power module does not exceed the preset value, the first transistor is turned off and the transistor is turned on.

4. The control circuit as claim 1, wherein the switch module further comprises a capacitor, the first terminal of the second transistor is grounded through the capacitor.

5. The control circuit as claim 4, wherein the first transistor is a NPN transistor and the second transistor is an n-channel FET.

6. The control circuit as claim 1, wherein the control module is an integrated controller.

7. The control circuit as claim 1, wherein the connecting module is a universal serial connector.

8. An electronic device, comprising:
a control circuit comprising a control module comprising:
a first port,
a second port, and
a switch module comprising a first power terminal configured to receive power from the power module,
the first port is coupled to the power module, the second port is coupled to the switch module, the switch module is coupled to the connecting module;
the control module is configured to detect a level of power in the power module and output a control signal to the second port in event that the level of power in the power module exceeds a preset value;
the power module supplies power for the connecting module;
the switch module is configured to connect the first power terminal to the connecting module in event that the level of power in the power module does not exceed the preset value, the switch module disconnects the first power terminal from the connecting module, the power module stops supplying power for the connecting module.
